(19) United States
(12) Patent Application Publication
(10) Pub. No.: US 2025/0311115 A1
(43) Pub. Date: Oct. 2, 2025

(54) METHOD FOR MANUFACTURING PRINTED WIRING BOARD

(71) Applicant: IBIDEN CO., LTD., Ogaki (JP)

(72) Inventors: Susumu KAGOHASHI, Ogaki (JP); Jun SAKAI, Ibi-gun (JP); Kyohei YOSHIKAWA, Ogaki (JP)

(73) Assignee: IBIDEN CO., LTD., Ogaki (JP)

(21) Appl. No.: 19/089,966

(22) Filed: Mar. 25, 2025

(30) Foreign Application Priority Data
Mar. 26, 2024 (JP) 2024-048873

(51) Int. Cl. H05K 3/46; H05K 1/03; H05K 1/11; H05K 3/00; H05K 3/07; H05K 3/38

(52) U.S. Cl. CPC H05K 3/4644; H05K 1/0373; H05K 1/113; H05K 1/116; H05K 3/0055; H05K 3/07; H05K 3/388; H05K 2201/0209; H05K 2201/0242; H05K 2201/0263; H05K 2201/09454; H05K 2201/09481; H05K 2201/096

(57) ABSTRACT

A method for manufacturing a printed wiring board includes forming a resin insulating layer on a first conductor layer, forming a protective film on a surface of the insulating layer, forming an opening through the film and the resin insulating layer, removing the film, treating the surface of the insulating layer, forming a second conductor layer on the surface of the resin insulating layer, and forming a via conductor connecting the first and second conductor layers. The insulating layer includes resin and inorganic particles including first and second particles. The surface of the insulating layer includes a surface of the resin and substantially flat exposed portions of the first particles, and the forming the second conductor layer includes forming a seed layer by sputtering, forming a plating resist using DI exposure, forming an electrolytic plating layer, removing the resist, and removing the seed layer exposed from the electrolytic plating layer.

### CROSS-REFERENCE TO RELATED APPLICATIONS

The present application is based upon and claims the benefit of priority to Japanese Patent Application No. 2024-048873, filed Mar. 26, 2024, the entire contents of which are incorporated herein by reference.

### BACKGROUND OF THE INVENTION

### Field of the Invention

The present invention relates to a method for manufacturing a printed wiring board.

### Description of Background Art

Japanese Patent Application Laid-Open Publication No. 2001-217526 describes a method for manufacturing a printed wiring board. The entire contents of this publication are incorporated herein by reference.

### SUMMARY OF THE INVENTION

According to one aspect of the present invention, a method for manufacturing a printed wiring board includes forming a resin insulating layer on a first conductor layer, forming a protective film on a surface of the resin insulating layer, forming a via conductor opening penetrates through the protective film and the resin insulating layer such that the via conductor opening reaches the first conductor layer, removing the protective film from the resin insulating layer after the forming of the via conductor opening, treating the surface of the resin insulating layer after the removing of the protective film, forming a second conductor layer on the surface of the resin insulating layer after the treating of the surface of the resin insulating layer, and forming a via conductor in the via conductor opening such that the via conductor connects the first conductor layer and the second conductor layer. The resin insulating layer includes resin and inorganic particles including first particles and second particles such that the first particles have substantially truncated spherical shapes and are forming the surface of the resin insulating layer and the second particles have substantially spherical shapes and are embedded in the resin, the treating the surface of the resin insulating layer includes forming the first particles from the second particles such that the surface of the resin insulating layer includes a surface of the resin and substantially flat exposed portions of the first particles, and the forming the second conductor layer includes forming a seed layer on the surface of the resin insulating layer by sputtering, forming a plating resist on the seed layer using DI exposure, forming an electrolytic plating layer on the seed layer exposed from the plating resist, removing the plating resist, and removing the seed layer exposed from the electrolytic plating layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view schematically illustrating a printed wiring board according to an embodiment of the present invention;

FIG. 2 is an enlarged cross-sectional view schematically illustrating a part of a printed wiring board according to an embodiment of the present invention;

FIG. 3 is an enlarged cross-sectional view schematically illustrating a part of a printed wiring board according to an embodiment of the present invention;

FIG. 4 is an enlarged cross-sectional view schematically illustrating a part of a printed wiring board according to an embodiment of the present invention;

FIG. 5 is an enlarged cross-sectional view schematically illustrating a part of a printed wiring board according to an embodiment of the present invention;

FIG. 6A is a cross-sectional view schematically illustrating a method for manufacturing a printed wiring board according to an embodiment of the present invention;

FIG. 6B is a cross-sectional view schematically illustrating a method for manufacturing a printed wiring board according to an embodiment of the present invention;

FIG. 6C is a cross-sectional view schematically illustrating a method for manufacturing a printed wiring board according to an embodiment of the present invention;

FIG. 6D is an enlarged cross-sectional view schematically illustrating a method for manufacturing a printed wiring board according to an embodiment of the present invention;

FIGS. 6E(a)-6E(c) are enlarged cross-sectional views schematically illustrating a method for manufacturing a printed wiring board according to an embodiment of the present invention;

FIG. 6F is a cross-sectional view schematically illustrating a method for manufacturing a printed wiring board according to an embodiment of the present invention; and

FIG. 7 is an enlarged cross-sectional view schematically illustrating a method for manufacturing a printed wiring board according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

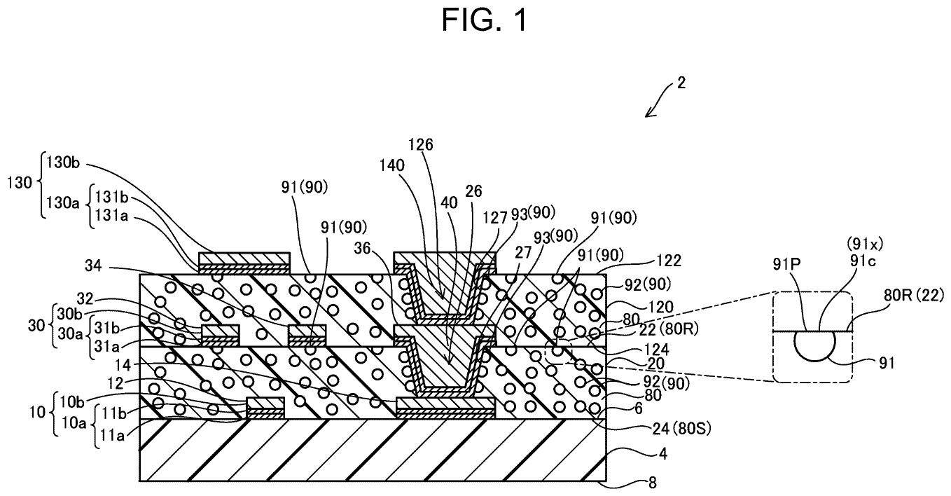

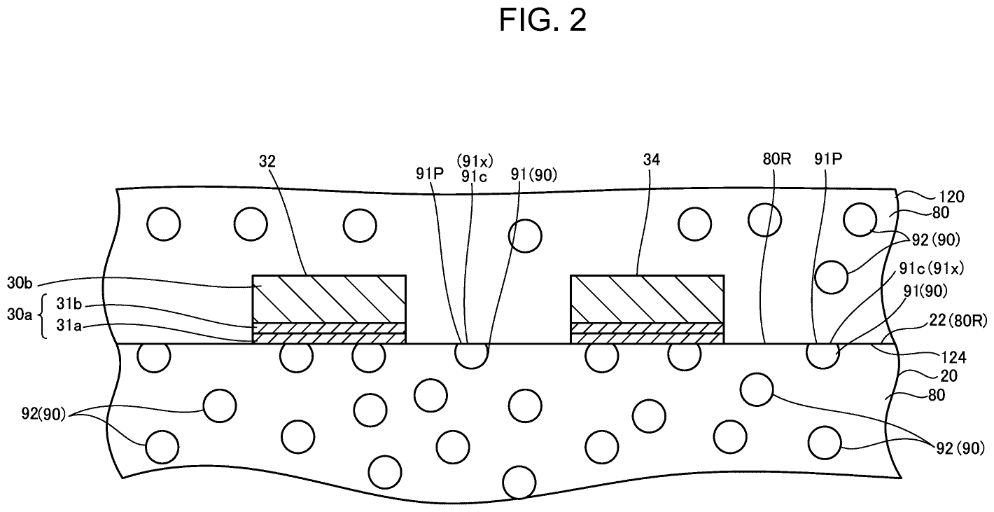

FIG. 1 is a cross-sectional view illustrating a printed wiring board 2 according to an embodiment of the present invention. FIGS. 2-5 are each an enlarged cross-sectional view illustrating a part of the printed wiring board 2 of the embodiment. As illustrated in FIG. 1, the printed wiring board 2 has an insulating layer 4, a conductor layer (first conductor layer) 10, a resin insulating layer (first resin insulating layer) 20, a conductor layer (second conductor layer) 30, a via conductor 40, a resin insulating layer (second resin insulating layer) 120, a conductor layer (third conductor layer) 130, and a via conductor 140.

The insulating layer 4 is formed using a resin. The insulating layer 4 may contain inorganic particles such as silica particles. The insulating layer 4 may contain a reinforcing material such as a glass cloth. The insulating layer 4 has a third surface 6 and a fourth surface 8 on the opposite side with respect to the third surface 6.

The first conductor layer 10 is formed on the third surface 6 of the insulating layer 4. The first conductor layer 10 includes a signal wiring 12 and a pad 14. Although not illustrated in the drawings, the first conductor layer 10 also includes conductor circuits other than the signal wiring 12 and the pad 14. The first conductor layer 10 is mainly formed of copper. The first conductor layer 10 is formed of a seed layer (10a) on the insulating layer 4 and an electrolytic plating layer (10b) on the seed layer (10a). The seed layer (10a) has a thickness of less than 0.5 μm. The seed layer (10a) is formed of a first layer (11a) on the third surface 6 and a second layer (11b) on the first layer (11a). The first layer (11a) is in contact with the insulating layer 4. A ratio of a thickness of the first layer (11a) to a thickness of the second layer (11b) ((the thickness of the first layer)/(the thickness of the second layer)) is 0.25 or more and 0.7 or less. The second layer (11b) is preferably thicker than the first layer (11a).

The first layer (11a) is formed of an alloy (copper alloy) containing copper and a metal other than copper. For example, the first layer (11a) is formed of an alloy containing copper and aluminum. The first layer (11a) is formed of an alloy containing copper, aluminum, and a specific metal. Examples of the specific metal include nickel, zinc, gallium, silicon, and magnesium. The alloy preferably contains one type of specific metal, or two types of specific metals, or three types of specific metals. An example of the specific metal is silicon. A content of aluminum in the alloy is 1.0 at % or more and 15.0 at % or less. When the alloy contains a specific metal, a content of the specific metal in the alloy is 0.5 at % or more and 10.0 at % or less. The first layer (11a) may contain impurities. Examples of the impurities include oxygen and carbon. The first layer (11a) can contain oxygen or carbon. The first layer (11a) can contain oxygen and carbon. In the embodiment, the alloy further contains carbon. A content of carbon in the alloy is 50 ppm or less. The alloy further contains oxygen. A content of oxygen in the alloy is 100 ppm or less. The values of the contents of the elements described above are examples. Among the elements forming the first layer (11a), copper has the largest content. The content of aluminum is the next largest. When the alloy contains a specific metal, the content of the specific metal is less than the content of aluminum. Therefore, copper is a primary metal, aluminum is a first secondary metal, and the specific metal is a second secondary metal. A content of the impurities is smaller than the content of the specific metal.

The second layer (11b) is formed of copper. The electrolytic plating layer (10b) is formed of copper.

The content of copper in the copper alloy forming the first layer (11a) is greater than 90 at %. The content of copper in the alloy is less than 99 at %. The content of copper in the copper alloy is 98 at % or less. A content of copper forming the second layer (11b) is 99.9 at % or more. The content of copper in the second layer (11b) is preferably 99.95 at % or more. The electrolytic plating layer (10b) is formed of copper. A content of copper forming the electrolytic plating layer (10b) is 99.9 at % or more. The content of copper in the electrolytic plating layer (10b) is preferably 99.95 at % or more.

The resin insulating layer (first resin insulating layer) 20 is formed on the third surface 6 of the insulating layer 4 and on the first conductor layer 10. The first resin insulating layer 20 has a first surface 22 and a second surface 24 on the opposite side with respect to the first surface 22. The second surface 24 of the first resin insulating layer 20 faces the first conductor layer 10. The first resin insulating layer 20 has an opening (via conductor opening) 26 that exposes the pad 14. The opening 26 has a bottom diameter of 20 μm or more and 50 μm or less. The resin insulating layer (first resin insulating layer) 20 is formed of a resin 80 and a large number of inorganic particles 90 dispersed in the resin 80. The resin 80 has an upper surface (80R) and a lower surface (80S) on the opposite side with respect to the upper surface (80R). The upper surface (80R) forms the first surface 22, and the lower surface (80S) forms the second surface 24. The resin 80 is an epoxy resin. Examples of the resin include a thermosetting resin and a photocurable resin. The inorganic particles 90 are, for example, glass particles or alumina particles. The inorganic particles 90 preferably contain oxygen elements. The inorganic particles 90 have an average particle size of 0.5 μm or less. An amount of the inorganic particles 90 in the resin insulating layer 20 is 70 wt % or more.

As illustrated in FIGS. 1 and 2, the inorganic particles 90 include first inorganic particles 91 forming the first surface 22 and second inorganic particles 92 embedded in the resin 80. The second inorganic particles are completely embedded in the resin 80. The second inorganic particles 92 each have a substantially spherical shape. The first inorganic particles 91 are formed from the second inorganic particles 92. The first inorganic particles 91 are each formed by removing a part of a second inorganic particle 92. The first inorganic particles 91 each have a substantially truncated spherical shape. A truncated sphere is a solid obtained by cutting a sphere with a substantially flat surface. A solid obtained by cutting a sphere with a flat surface passing through the center of the sphere is a hemisphere, and a hemisphere is a type of truncated sphere. In the embodiment, a surface exposed by cutting a sphere with a substantially flat surface is referred to as a cut surface. A part of a surface of each of the first inorganic particles 91 is a substantial flat surface, and the flat surface is substantially flat. The flat surface forms a cut surface (91c) of a truncated sphere and faces the first surface 22. Alternatively, a part of the surface of each of the first inorganic particles 91 is a substantially curved surface, and the curved surface is substantially smooth. The curved surface forms a cut surface (91c) of a truncated sphere and faces the first surface 22. The first inorganic particles 91 are embedded in the resin 80 such that the cut surfaces (91c) form the first surface 22. The first surface 22 is formed by the cut surfaces (91c) of the first inorganic particles 91 and the upper surface (80R) of the resin 80. The cut surfaces (91c) and the upper surface (80R) form substantially the same surface. The cut surfaces (91c) are exposed from the upper surface (80R) of the resin 80. Of the surface of each of the first inorganic particles 91, a portion exposed by the upper surface (80R) of the resin 80 is an exposed portion (91P). A surface (exposed surface) (91x) of the exposed portion (91P) forms the first surface 22. The exposed surface (first exposed surface) (91x) is a substantially flat surface or a substantially curved surface. The first exposed surface (91x) is substantially flat. The first exposed surface (91x) is substantially smooth. The first exposed surface (91x) and the cut surface (91c) are substantially the same surface. The first exposed surfaces (91x) and the upper surface (80R) of the resin 80 form the first surface 22. The first exposed surfaces (91x) and the upper surface (80R) form substantially the same surface.

The first surface 22 has an arithmetic mean roughness (Ra) of less than 0.08 μm. The roughness (Ra) of the first surface 22 is preferably 0.05 μm or less. The roughness (Ra) of the first surface 22 is more preferably 0.03 μm or less. The upper surface (80R) has an arithmetic mean roughness (Ra) of less than 0.08 μm. The roughness (Ra) of the upper surface (80R) is preferably 0.05 μm or less. The roughness (Ra) of the upper surface (80R) is more preferably 0.03 μm or less.

The first surface 22 can have steps (first steps) between the first exposed surfaces (91x) and the upper surface (80R). The first exposed surfaces (91x) protrude relative to the upper surface (80R). Alternatively, the first exposed surfaces (91x) are recessed relative to the upper surface (80R). Preferably, the first exposed surfaces (91x) protrude relative to the upper surface (80R). Sizes of the steps (first steps) (distances between the first exposed surfaces (91x) and the upper surface (80R) of the resin 80) are 5 μm or less. The sizes of the first steps are preferably 3 μm or less. The sizes of the first steps are more preferably 1.5 μm or less. Even when the steps (first steps) are formed, since the steps are small, the first exposed surfaces (91x) and the upper surface (80R) of the resin 80 form a substantially common surface. For example, the sizes of the steps are represented by a maximum value.

A ratio (R) of a volume of a first inorganic particle 91 to a volume of a sphere (assumed sphere) predicted from the first inorganic particle 91 ((volume of a first inorganic particle)/(volume of an assumed sphere)) is 0.6 or more and less than 1. The ratio (R) is preferably 0.8 or more. The ratio (R) is more preferably 0.9 or more. The ratio (R) is most preferably 0.95 or more. The ratio (R) is preferably 0.97 or less. A thermal expansion coefficient of the resin 80 near the upper surface (80R) is controlled.

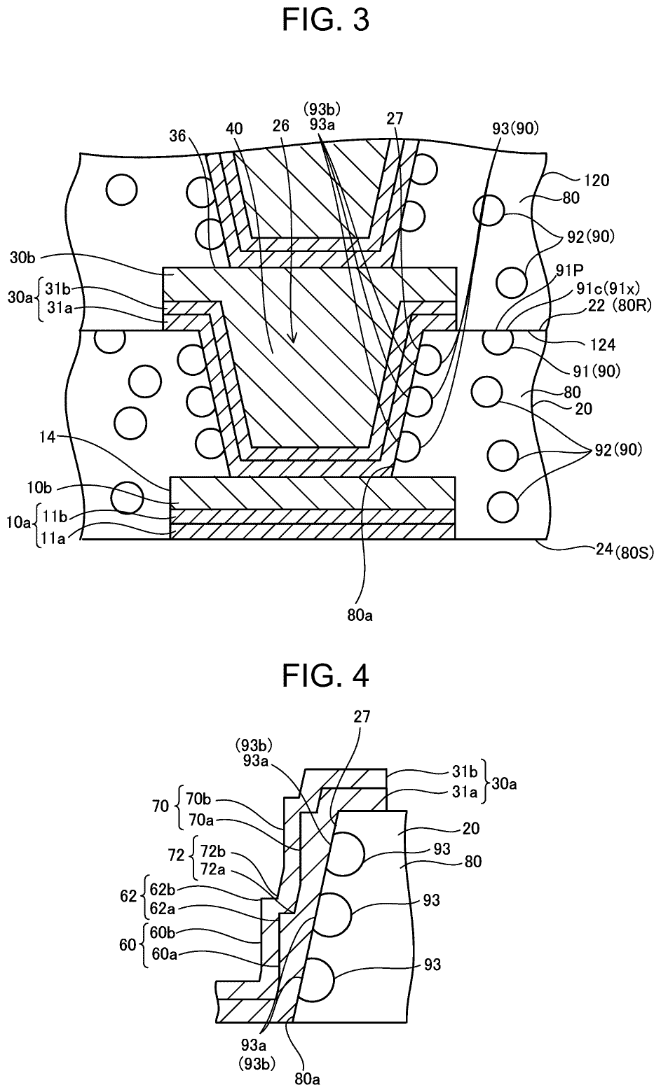

As illustrated in FIGS. 1 and 3, the inorganic particles 90 further include third inorganic particles 93 that form an inner wall surface (first inner wall surface) 27 of the opening (via conductor opening) 26. The third inorganic particles 93 each have a shape obtained by cutting a sphere with a flat surface. The third inorganic particles 93 each have a shape obtained by cutting a second inorganic particle 92 with a flat surface. The third inorganic particles 93 are formed from the second inorganic particles 92. The third inorganic particles 93 are each formed by removing a part of a second inorganic particle 92. The third inorganic particles 93 each have substantially a truncated spherical shape. The first inorganic particles 91 and the third inorganic particles 93 are substantially similar in shape. The first inorganic particle 91 and the third inorganic particle 93 are substantially similar in appearance. The first inorganic particle 91 and the third inorganic particle 93 may be different in size. The third inorganic particles 93 each have a flat part (93a). The flat parts (93a) form the inner wall surface 27. The inner wall surface 27 is formed of the resin 80 and the flat parts (93a). The flat parts (93a) and a surface (first resin surface) (80a) of the resin 80 that forms the inner wall surface 27 form a substantially common surface. No unevenness is formed on the resin 80 that forms the inner wall surface 27. The surface (80a) of the resin 80 that forms the inner wall surface 27 is substantially smooth. No unevenness is formed on exposed surfaces (93b) of the flat parts (93a) (surfaces that form the inner wall surface 27). The exposed surfaces (second exposed surfaces) (93b) of the flat parts (93a) are smooth. The inner wall surface 27 is formed smooth. The inner wall surface 27 has an arithmetic mean roughness (Ra) of 1.0 μm or less. The surface (80a) of the resin 80 that forms the inner wall surface 27 has a roughness (Ra) of 1.0 μm or less.

The inner wall surface 27 can have steps (second steps) between the flat parts (93a) and the surface (80a) of the resin 80 that forms the inner wall surface 27. The exposed surfaces (second exposed surfaces) (93b) of the flat parts (93a) protrude relative to the surface (80a) of the resin 80 that forms the inner wall surface 27. Alternatively, the exposed surfaces (93b) of the flat parts (93a) are recessed relative to the surface (80a) of the resin 80 that forms the inner wall surface 27. Preferably, the exposed surfaces (93b) protrude relative to the surface (80a). Sizes of the steps (second steps) (distances between the exposed surfaces (93b) of the flat parts (93a) and the surface (80a) of the resin 80 that forms the inner wall surface 27) are 5 μm or less. The sizes of the second steps are preferably 3 μm or less. The sizes of the second steps are more preferably 1.5 μm or less. Even when the steps (second steps) are formed, since the steps are small, the exposed surfaces (93b) of the flat parts (93a) and the surface (80a) of the resin 80 that forms the inner wall surface 27 form a substantially common surface. When the first exposed surfaces (91x) protrude, the second exposed surfaces (93b) also protrude. When the first exposed surfaces (91x) are recessed, the second exposed surfaces (93b) also are recessed.

As illustrated in FIG. 1, the second conductor layer 30 is formed on the first surface 22 of the resin insulating layer (first resin insulating layer) 20. The second conductor layer 30 includes a first signal wiring 32, a second signal wiring 34, and a land 36. Although not illustrated in the drawings, the second conductor layer 30 also includes conductor circuits other than the first signal wiring 32, the second signal wiring 34, and the land 36. The first signal wiring 32 and the second signal wiring 34 form a pair wiring. The first signal wiring 32 and the second signal wiring 34 are adjacent to each other.

The conductor layer (second conductor layer) 30 is mainly formed of copper. The second conductor layer 30 is formed of a seed layer (30a) on the first surface 22 and an electrolytic plating layer (30b) on the seed layer (30a). The seed layer (30a) is formed of a first layer (31a) on the first surface 22 and a second layer (31b) on the first layer (31a). The seed layer (30a) has a thickness of less than 0.5 μm. The first conductor layer 10 and the second conductor layer 30 are similar. A relationship between the thickness of the first layer (31a) and the thickness of the second layer (31b) is similar to the relationship between the thickness of the first layer (11a) and the thickness of the second layer (11b). The first layer (31a) and the second layer (31b) form the second conductor layer 30, and the first layer (11a) and the second layer (11b) form the first conductor layer 10. The first layer (31a) is formed of an alloy (copper alloy) similar to the first layer (11a). The second layer (31b) is formed of copper. The electrolytic plating layer (30b) is formed of copper. The first layer (31a) is in contact with the first surface 22.

The via conductor (first via conductor) 40 is formed in the opening (via conductor opening) 26. The opening 26 penetrates the first resin insulating layer 20 and reaches the first conductor layer 10. The via conductor (first via conductor) 40 connects the first conductor layer 10 and the second conductor layer 30. In FIG. 1, the via conductor 40 connects the pad 14 and the land 36. The via conductor 40 is formed of a seed layer (30a) and an electrolytic plating layer (30b) on the seed layer (30a). The seed layer (30a) forming the via conductor 40 and the seed layer (30a) forming the second conductor layer 30 are common. The first layer (31a) forming the via conductor 40 and the first layer (31a) forming the second conductor layer 30 are common. The first layer (31a) is in contact with the inner wall surface 27. The second layer (31b) forming the via conductor 40 and the second layer (31b) forming the second conductor layer 30 are common. The electrolytic plating layer (30b) forming the via conductor 40 and the electrolytic plating layer (30b) forming the second conductor layer 30 are common.

The first layer (11a) forming the first conductor layer 10, the first layer (31a) forming the second conductor layer 30, and the first layer (31a) forming the via conductor 40 are similar. The first layers (11a, 31a) are formed of the same elements. Contents of each of the elements forming the first layers (11a, 31a) are similar. The second layer (11b) forming the first conductor layer 10, the second layer (31b) forming the second conductor layer 30, and the second layer (31b) forming the via conductor 40 are similar. The second layers (11b, 31b) are formed of the same elements. The second layers (11b, 31b) are formed of substantially the same amounts of the elements. The electrolytic plating layer (10b) forming the first conductor layer 10, the electrolytic plating layer (30b) forming the second conductor layer 30, and the electrolytic plating layer (30b) forming the via conductor 40 are similar. The electrolytic plating layers (10b, 30b) are formed of the same elements. The electrolytic plating layers (10b, 30b) are formed of substantially the same amounts of the elements.

As illustrated in FIG. 4, the seed layer (30a) forming the via conductor 40 may have a substantially smooth first portion (first film) 60 and a substantially smooth second portion (second film) 70. The first portion 60 and the second portion 70 are electrically connected. The first portion 60 and second portion 70 are continuous. A part of the first portion 60 is formed on the second portion 70. A leading end 62 of the first portion 60 is formed on a trailing end 72 of the second portion 70. The first portion 60 and the second portion 70 are formed at the same time. The seed layer (30a) covering the inner wall surface 23 has a substantially step-shaped cross section.

As illustrated in FIG. 4, the first layer (31a) of the seed layer (30a) has a first portion (first film) (60a) and a second portion (second film) (70a). The first portion (60a) and the second portion (70a) are electrically connected. The first portion (60a) and the second portion (70a) are continuous. A leading end (62a) of the first portion (60a) is formed on a trailing end (72a) of the second portion (70a). The first layer (31a) covering the inner wall surface 23 has a substantially step-shaped cross section. The first layer (31a) on the inner wall surface 27 is in contact with the inner wall surface 27.

The second layer (31b) of the seed layer (30a) has a first portion (first film) (60b) and a second portion (second film) (70b). The first portion (60b) and the second portion (70b) are electrically connected. A leading end (62b) of the first portion (60b) is formed on a trailing end (72b) of the second portion (70b). The second layer (31b) formed on the inner wall surface 23 has a substantially step-shaped cross section.

A part of the first portion 60 is laminated on the second portion 70. A part of the first portion 60 overlaps the second portion 70. The leading end 62 of the first portion 60 is laminated on the trailing end 72 of the second portion 70. The leading end 62 of the first portion 60 overlaps the trailing end 72 of the second portion 70.

The second resin insulating layer 120 is formed on the second conductor layer 30 and the first surface 22 of the first resin insulating layer 20. The second resin insulating layer 120 has a first surface 122 and a second surface 124 on the opposite side with respect to the first surface 122. The second surface 124 of the second resin insulating layer 120 faces the second conductor layer 30. The second resin insulating layer 120 has an opening (via conductor opening) 126. The opening 126 penetrates the second resin insulating layer 120 and reaches the second conductor layer 30.

The second resin insulating layer 120 is formed of a resin 80 and inorganic particles 90. The first resin insulating layer 20 and the second resin insulating layer 120 are similar. Therefore, the resin 80 forming the second resin insulating layer 120 and the resin 80 forming the first resin insulating layer 20 are similar. The inorganic particles 90 forming the second resin insulating layer 120 and the inorganic particles 90 forming the first resin insulating layer 20 are similar. Similar to the first resin insulating layer 20, the inorganic particles 90 forming the second resin insulating layer 120 include first inorganic particles 91, second inorganic particles 92 and third inorganic particles 93. The first inorganic particles 91 in the first resin insulating layer 20 and the first inorganic particles 91 in the second resin insulating layer 120 are similar. The second inorganic particles 92 in the first resin insulating layer 20 and the second inorganic particles 92 in the second resin insulating layer 120 are similar. The third inorganic particles 93 in the first resin insulating layer 20 and the third inorganic particles 93 in the second resin insulating layer 120 are similar.

The first surface 22 of the first resin insulating layer 20 and the first surface 122 of the second resin insulating layer 120 are similar. The first surface 122 of the resin insulating layer (second resin insulating layer) 120 is formed by an upper surface (second upper surface) of the resin 80 forming the resin insulating layer (second resin insulating layer) 120 and exposed surfaces (third exposed surfaces) of exposed portions of the first inorganic particles 91 forming the resin insulating layer (second resin insulating layer) 120. The second upper surface and the third exposed surfaces form a substantially common surface. Similar to the first surface 22 of the first resin insulating layer 20, the first surface 122 of the second resin insulating layer 120 can have steps (third steps) between the second upper surface and the third exposed surfaces. The first steps and the third steps are similar. The sizes of the first steps and sizes of the third steps are similar. Even when the first surface 122 has the steps, since the sizes of the steps are small, the upper surface (second upper surface) of the resin 80 and the exposed surfaces (third exposed surfaces) of the first inorganic particles 91 are positioned substantially on the same surface.

The opening (via conductor opening) 126 penetrating the second resin insulating layer 120 and the opening (via conductor opening) 26 penetrating the first resin insulating layer 20 are similar. Therefore, an inner wall surface (second inner wall surface) 127 of the opening 126 and the inner wall surface (first inner wall surface) 27 of the opening 26 are similar. The second inner wall surface 127 is formed by the resin 80 and the flat parts (93a) of the third inorganic particles 93. Similar to the first inner wall surface 27, the second inner wall surface 127 is formed by the surface (second resin surface) of the resin 80 forming the second inner wall surface 127 and the flat parts (93a) of the third inorganic particles 93 forming the second resin insulating layer 120. Similar to the flat parts (93a) of the third inorganic particles 93 that form the first resin insulating layer 20, the flat parts (93a) of the third inorganic particles 93 that form the second resin insulating layer 120 each have an exposed surface (fourth exposed surface). The second resin surface and the fourth exposed surfaces forming the inner wall surface 127 form a substantially common surface. Similar to the first inner wall surface 27, the second inner wall surface 127 can have steps (fourth steps) between the second resin surface and the fourth exposed surfaces. The second steps and the fourth steps are similar. Sizes of the fourth steps and the sizes of the second steps are similar. Thus, even when the second inner wall surface 127 has the fourth steps, the second resin surface and the fourth exposed surfaces form a substantially common surface.

As illustrated in FIG. 1, the third conductor layer 130 is formed on the first surface 122 of the second resin insulating layer 120. The via conductor (second via conductor) 140 that connects the second conductor layer 30 and the third conductor layer 130 is formed in the opening 126. The third conductor layer 130 and the second conductor layer 30 are similar. The second via conductor 140 and the first via conductor 40 are similar. The third conductor layer 130 and the second via conductor 140 are formed of a seed layer (130a) including a first layer (131a) and a second layer (131b) on the first layer (131a), and an electrolytic plating layer (130b) on the seed layer (130a). The first layer (131a) forming the third conductor layer 130 and the second via conductor 140 is similar to the first layer (31a) of the second conductor layer 30. The second layer (131b) forming the third conductor layer 130 and the second via conductor 140 is similar to the second layer (31b) of the second conductor layer 30. The electrolytic plating layer (130b) forming the third conductor layer 130 and the second via conductor 140 is similar to the electrolytic plating layer (30b) of the second conductor layer 30. The first layer (131a) is in contact with the first surface 122 of the second resin insulating layer 120. The first layer (131a) is in contact with the inner wall surface (second inner wall surface) 127. The layers (the first layer (31a), the second layer (31b), and the electrolytic plating layer (30b)) forming the second conductor layer 30 and the layers (the first layer (131a), the second layer (131b), and the electrolytic plating layer (130b)) forming the third conductor layer 130 have similar thicknesses and compositions. The layers (the first layer (31a), the second layer (31b), and the electrolytic plating layer (30b)) forming the second conductor layer 30 and the layers (the first layer (131a), the second layer (131b), and the electrolytic plating layer (130b)) forming the third conductor layer 130 are formed of the same elements. Contents of the elements contained in the layers (the first layer (31a), the second layer (31b), and the electrolytic plating layer (30b)) forming the second conductor layer 30 and contents of the elements contained in the layers (the first layer (131a), the second layer (131b), and the electrolytic plating layer (130b)) forming the third conductor layer 130 are similar.

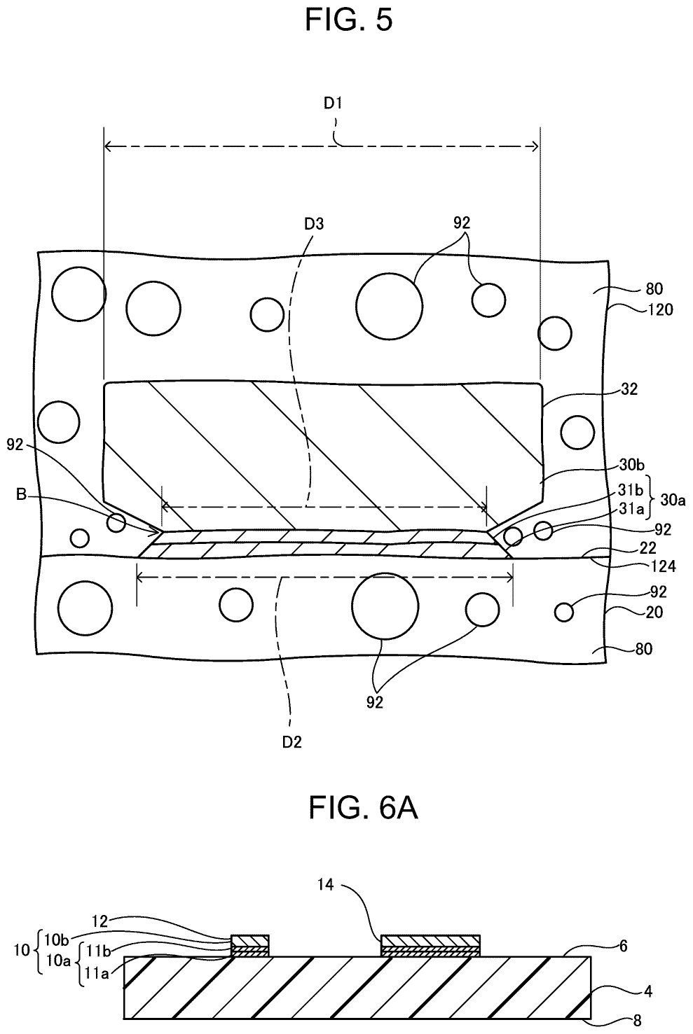

FIG. 5 illustrates an enlarged cross-sectional view of the first signal wiring 32 of the second conductor layer 30. As illustrated in FIG. 5, the first signal wiring 32 is formed by the seed layer (30a) on the first surface 22 of the first resin insulating layer 20 and the electrolytic plating layer (30b) on the seed layer (30a). The seed layer (30a) includes the first layer (31a) on the first surface 22 and the second layer (31b) on the first layer (31a). The first layer (31a) is in contact with the first surface 22. The electrolytic plating layer (30b) is formed directly on the second layer (31b).

As illustrated in FIG. 5, a width of the seed layer (30a) of the first signal wiring 32 (a length in a left-right direction in the drawing) is smaller than a width of the electrolytic plating layer (30b). The width of the first signal line 32 is smallest at a boundary portion (B) between the seed layer (30a) and the electrolytic plating layer (30b). A width (D2) of the first layer (31a) is larger than a width (D3) of the second layer (31b), and a width (D1) of the electrolytic plating layer (30b) is larger than the width (D2) of the first layer (31a).

As illustrated in FIG. 5, the widths (D1, D2, D3) are distances between side surfaces of the first signal wiring 32. The width (D1) is a distance between side surfaces of the first signal wiring 32. The width (D1) is measured near an upper surface of the first signal wiring 32. The upper surface of the first signal wiring 32 is a surface away from the first surface 22. The width (D2) is measured on the first surface 22. The width (D3) is measured at an interface between the second layer (31b) and the electrolytic plating layer (30b).

FIG. 5 illustrates the first signal wiring 32. However, other conductor circuits (the second signal wiring 34 and the land 36) in the second conductor layer 30 also have the same structure as the first signal wiring 32. The conductor circuits in the third conductor layer 130 also have the same structure as the first signal wiring 32.

A length of each side of the printed wiring board 2 is 50 mm or more. The length of each side is preferably 100 mm or more. The length of each side is 250 mm or less.

The printed wiring board 2 can have a solder resist layer on the first surface 122 of the second resin insulating layer 120 and on the third conductor layer 130. The insulating layer 4 may form a core material.

### Method for Manufacturing Printed Wiring Board

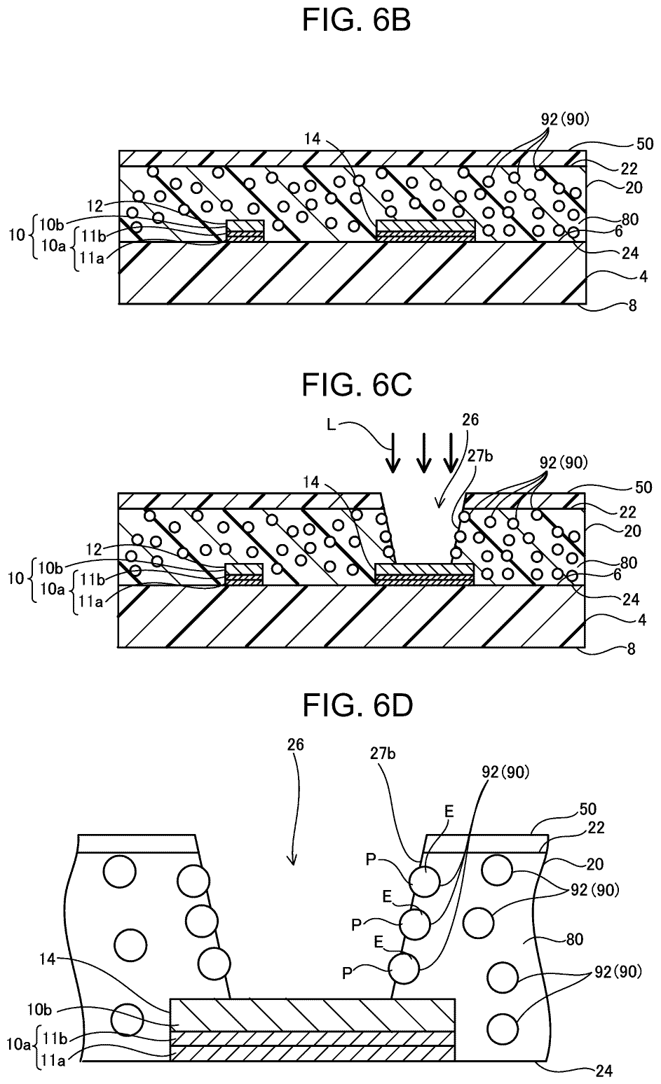

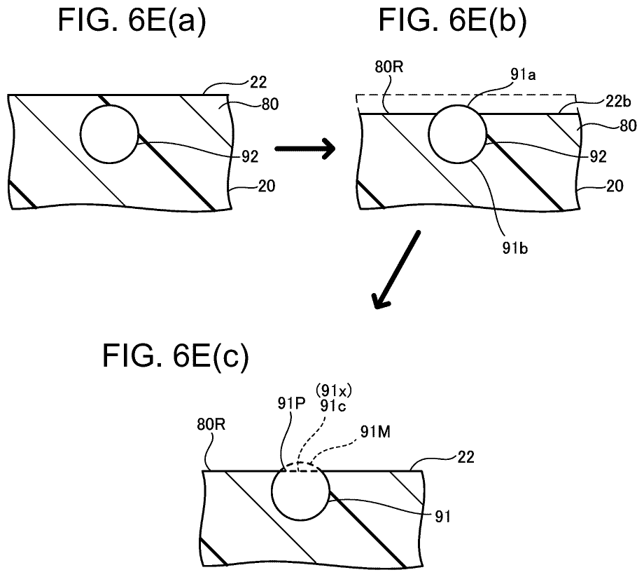

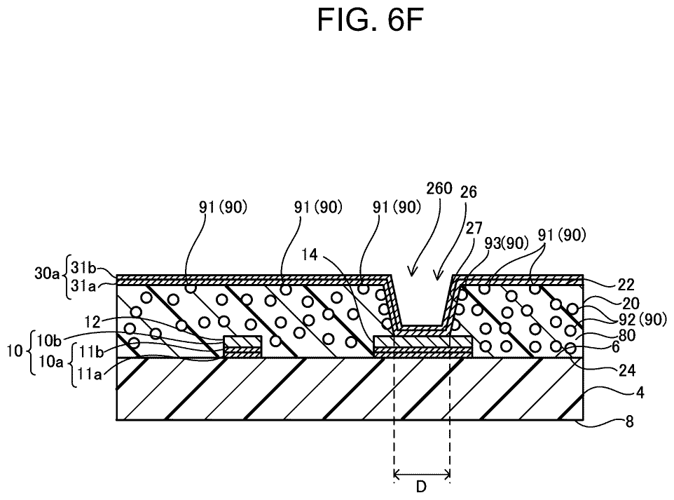

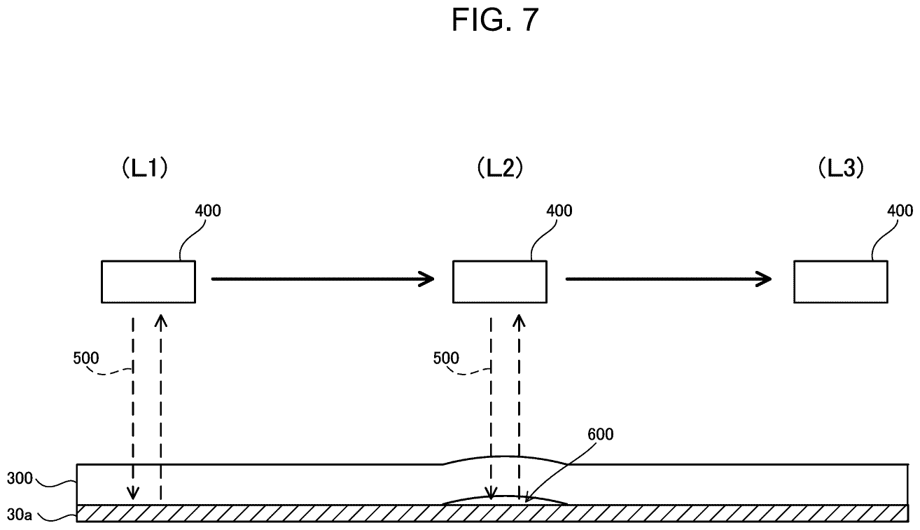

FIGS. 6A-6F and 7 illustrate a method for manufacturing the printed wiring board 2 of the embodiment. FIGS. 6A-6C and 6F are cross-sectional views. FIGS. 6D, 6E(a)-6E (c) and 7 are enlarged cross-sectional views. FIG. 6A illustrates the insulating layer 4 and the conductor layer (first conductor layer) 10 formed on the third surface 6 of the insulating layer 4. The first conductor layer 10 is formed using a semi-additive method. The first layer (11a) and the second layer (11b) are formed by sputtering. The first layer (11a) and the second layer (11b) are formed in vacuum. The electrolytic plating layer (10b) is formed by electrolytic plating.

As illustrated in FIG. 6B, the resin insulating layer (first resin insulating layer) 20 and a protective film 50 are formed on the insulating layer 4 and the first conductor layer 10. Forming the resin insulating layer 20 and the protective film 50 on the insulating layer 4 and the first conductor layer 10 includes forming the resin insulating layer 20 on the insulating layer 4 and the first conductor layer 10 and forming the protective film 50 on the resin insulating layer 20. The forming of the resin insulating layer 20 and the protective film 50 on the insulating layer 4 and the first conductor layer 10 includes forming the resin insulating layer 20 with the protective film 50 on the insulating layer 4 and the first conductor layer 10. A manufacturing method that includes forming the resin insulating layer 20 on the first conductor layer 10 and forming the protective film 50 on the resin insulating layer 20 includes a manufacturing method that includes preparing the resin insulating layer 20 with the protective film 50 and forming the resin insulating layer 20 with the protective film 50 on the first conductor layer 10. The second surface 24 of the resin insulating layer 20 faces the third surface 6 of the insulating layer 4. The protective film 50 is formed on the first surface 22 of the first resin insulating layer 20. The resin insulating layer 20 contains the resin 80 and the inorganic particles 90. The inorganic particles 90 are embedded in the resin 80. An example of the inorganic particles 90 is glass particles.

The protective film 50 completely covers the first surface 22 of the resin insulating layer 20. An example of the protective film 50 is a film formed of polyethylene terephthalate (PET). A release agent is formed between the protective film 50 and the resin insulating layer 20.

As illustrated in FIG. 6C, laser (L) is irradiated from above the protective film 50. The laser (L) penetrates the protective film 50 and the resin insulating layer 20 at the same time. The opening (via conductor opening) 26 reaching the pad 14 of the first conductor layer 10 is formed. An inner wall surface (27b) of the opening 26 after the laser irradiation is formed. The laser (L) is, for example, UV laser, or CO2 laser. The pad 14 is exposed from the opening 26. When the opening 26 is formed, the first surface 22 is covered by the protective film 50. Therefore, when the opening 26 is formed, even when the resin scatters, adherence of the resin to the first surface 22 is suppressed.

FIG. 6D illustrates the inner wall surface (27b) of the opening 26 after the laser irradiation. By irradiating the resin insulating layer 20 with the laser (L), some of the second inorganic particles 92 embedded in the resin 80 form the inner wall surface (27b) after the laser irradiation. The inner wall surface (27b) is formed of the resin 80 and the inorganic particles 90 protruding from the resin 80. Some of the second inorganic particles embedded in the resin insulating layer 20 partially protrude from the inner wall surface (27b). The second inorganic particles 92 forming the inner wall surface (27b) after the laser irradiation are each formed of a protruding portion (P) protruding from the resin 80 and a portion (E) embedded in the resin 80. The second inorganic particles 92 forming the inner wall surface (27b) are referred to as third protruding particles.

The protective film 50 is removed. After removing the protective film 50, the first surface 22 of the resin insulating layer 20 is cleaned. The resin 80 forming the first surface 22 is removed by a dry process. For example, the first surface 22 of the resin insulating layer 20 is cleaned by reverse sputtering. For example, cleaning the first surface 22 of the resin insulating layer 20 is performed by sputtering using an argon gas (argon sputtering). FIGS. 6E(a) and 6E(b) schematically illustrate the first surface 22 of the resin insulating layer 20 before and after the cleaning. As illustrated in FIGS. 6E(a) and 6E(b), about 20 nm of the resin 80 forming the resin insulating layer 20 is removed by the cleaning by sputtering or the like. For example, an adhesive used to adhere the protective film 50 to the resin insulating layer 20 is removed. By the cleaning, the resin 80 is selectively removed. The resin 80 is reduced in thickness. Some of the inorganic particles 90 are partially exposed from the upper surface (80R) of the resin 80 by the cleaning. Some of the second inorganic particles 92 are exposed from the upper surface (80R) of the resin 80. FIG. 6E(b) illustrates the first surface (22b) after the cleaning. As illustrated in FIG. 6E (b), the inorganic particles (second inorganic particles 92) 90 that form the first surface (22b) after the cleaning are each formed of a first portion (91a) that protrudes from the resin 80 and a second portion (91b) that is embedded in the resin 80. The second inorganic particles 92 that form the first surface (22b) after the cleaning are referred to as first protruding particles.

In order to control a shape of the inner wall surface, the inner wall surface (27b) after the laser irradiation is treated. In order to control a shape of the first surface, the first surface (22b) after the cleaning is treated. It is preferable that the first protruding particles and the third protruding particles are selectively removed. As a result, the first inorganic particles 91 are formed from the inorganic particles 90. The third inorganic particles 93 are formed from the inorganic particles 90. For example, the first protruding particles and the third protruding particles are selectively removed by treating the inner wall surface (27b) after the laser irradiation and the first surface (22b) after the cleaning with a chemical. Or, the first protruding particles and the third protruding particles are selectively removed by treating the inner wall surface (27b) after the laser irradiation and the first surface (22b) after the cleaning with plasma. The selectively removing includes that an etching rate of the inorganic particles 90 is greater than an etching rate of the resin 80. For example, a difference in etching rate between the two is 10 or more times. Alternatively, the difference in etching rate between the two is 50 or more times. Alternatively, the difference in etching rate between the two is 100 or more times. By treating the first surface (22b) after the cleaning, the first inorganic particles 91 having the exposed portions (91P) are obtained. By treating the inner wall surface (27b) after the laser irradiation, the third inorganic particles 93 having the flat parts (93a) are obtained. By controlling conditions for treating the first surface (22b) after the cleaning, the embodiment can control the shape of the first surface 22. By controlling conditions for treating the inner wall surface (27b) after the laser irradiation, the embodiment can control the shape of the inner wall surface 27. Examples of the conditions are a temperature, a concentration, a time, a type of gas, and a pressure. The etching rate of the inorganic particles 90 and the etching rate of the resin are controlled.

The inner wall surface (27b) after the laser irradiation is treated. For example, the inner wall surface (27b) is treated with plasma of a gas containing tetrafluoromethane. By selectively removing the protruding portions (P), the inner wall surface 27 of the embodiment is formed. By treating the inner wall surface (27b), the third inorganic particles 93 are formed from the second inorganic particles 92. By selectively removing the protruding portions (P), the third inorganic particles 93 having the flat parts (93a) are formed. The surface forming the flat parts (93a) is a substantially flat surface. The surface forming the flat parts (93a) is a substantially curved surface. When the second inorganic particles 92 having substantially spherical shapes are cut with a flat surface, the shapes of the third inorganic particles 93 are obtained. Alternatively, the second inorganic particles 92 are cut along a curved surface. The third inorganic particles 93 each have a substantially truncated spherical shape. The inner wall surface 27 is formed by the flat parts (93a) and the surface (80a) of the resin 80. The exposed surfaces (93b) of the flat parts (93a) and the surface (80a) of the resin 80 are positioned substantially on the same flat surface. For example, when the seed layer (30a) is formed on the inner wall surface (27b) by sputtering, the protruding portions (P) inhibit growth of a sputtering film. For example, it is difficult to form a continuous seed layer (30a) on the inner wall surface (27b). Alternatively, the seed layer (30a) is increased in thickness. It is thought that in a printed wiring board having the third protruding particles, fine conductive circuits cannot be formed on the first surface 22. In the embodiment, the protruding portions (P) are removed. The embodiment can reduce the thickness of the seed layer (30a) formed by sputtering. Even when the seed layer (30a) formed by sputtering is thin, a continuous seed layer (30a) can be obtained. The seed layer (30a) has a thickness of 0.05 μm or more and less than 0.5 μm.

The forming of the opening 26 includes forming the inorganic particles 90 (the second inorganic particles 92) having the protruding portions (P). The protruding portions (P) protrude from the resin 80 that forms the inner wall surface (27b) of the opening 26. The third inorganic particles 93 are formed by removing the protruding portions (P) of the inorganic particles 90 (the second inorganic particles 92). The inner wall surface 27 of the opening 26 includes the exposed surfaces (93b) of the third inorganic particles 93. The exposed surfaces (93b) of the third inorganic particles 93 are formed by removing the protruding portions (P).

Obtaining the shapes of the third inorganic particles 93 by cutting the second inorganic particles 92 having substantially spherical shapes with a flat surface includes removing the protruding portions (P) of the inorganic particles 90. The actual inner wall surface 27 of the opening 26 is substantially a curved surface. Since the flat parts (93a) are formed by removing the protruding portions (P), the exposed surfaces (93b) of the flat parts (93a) each include a curved surface. That is, forming a common surface with the flat parts (93a) and the resin 80 includes forming the inner wall surface 27 formed with a substantially curved surface.

The first surface (22b) after the cleaning is treated. For example, the first surface (22b) is treated with plasma of a gas containing tetrafluoromethane. By selectively removing the first portions (91a), the first surface 22 of the embodiment is formed. By treating the first surface (22b), the first inorganic particles 91 are formed from the second inorganic particles 92. As illustrated in FIG. 6E (c), by selectively removing the first portion (91a), the first inorganic particle 91 having the exposed portion (91P) is formed. The exposed surface (first exposed surface) (91x) of the exposed portion (91P) is a substantially flat surface. It is also possible that the first exposed surface (91x) is a substantially curved surface. When the second inorganic particles 92 having substantially spherical shapes are cut along a flat surface, the shapes of the first inorganic particles 91 are obtained. Alternatively, the second inorganic particles 92 are cut along a curved surface. The first surface 22 is formed by the exposed portions (91P) and the upper surface (80R) of the resin 80. The first exposed surfaces (91x) of the exposed portions (91P) and the upper surface (80R) of the resin 80 are positioned on substantially the same surface. For example, when the seed layer (30a) is formed on the first surface (22b) by sputtering, the first portions (91a) inhibit growth of a sputtering film. For example, it is difficult to form a continuous seed layer (30a) on the first surface (22b). Alternatively, the seed layer (30a) is increased in thickness. It is thought that in a printed wiring board having the first protruding particles, fine conductive circuits cannot be formed on the first surface 22. In the embodiment, the first portions (91a) are removed. The embodiment can reduce the thickness of the seed layer (30a) formed by sputtering. Even when the seed layer (30a) formed by sputtering is thin, a continuous seed layer (30a) can be obtained. The seed layer (30a) has a thickness of 0.05 μm or more and less than 0.5 μm.

The forming of the first surface 22 includes forming the inorganic particles (second inorganic particles 92) 90 having the first portions (91a). The first portions (91a) protrude from the upper surface (80R) of the resin 80. The first inorganic particles 91 are formed by removing the first portions (91a) of the inorganic particles (second inorganic particles 92) 90. The first surface 22 includes the exposed surfaces (91x) of the first inorganic particles 91. The exposed surfaces (91x) of the first inorganic particles 91 are formed by removing the first portions (91a).

The obtaining of the shapes of the first inorganic particles 91 by cutting the second inorganic particles 92 having substantially spherical shapes along a flat surface includes removing the first portions (91a) of the inorganic particles 90. Since the exposed portions (91P) are formed by removing the first portions (91a), the exposed surfaces (91x) of the exposed portions (91P) each include a curved surface. That is, the exposed surfaces (91x) each include a substantially curved surface.

For example, using FIG. 6E(c), the ratio (R) ((the volume of the first inorganic particle)/(the volume of the assumed sphere)) is determined. The cross-sectional view in FIGS. 6E(a)-6E(c) are perpendicular to the first surface 22. The outer perimeter of the first inorganic particles 91 is depicted with a solid line and a broken line. The first exposed surface (91x) is depicted with a broken line, while the outer periphery of the portion other than the first exposed surface (91x) is depicted with a solid line. Using the plan view of the first inorganic particle 91 in FIG. 6E(c), a circle (assumed circle) (91M) is envisioned. A circumference of the assumed circle (91M) is depicted with a dotted line and a solid line. A portion illustrated with the dotted line represents a portion predicted from the first inorganic particle 91. The first inorganic particle 91 has a truncated spherical shape. Since the shape of the first inorganic particle 91 originates from a sphere, the assumed circle can be relatively easily predicted. An area of the first inorganic particle 91 in FIG. 6E (c) is determined. An area of the assumed circle in FIG. 6E (c) is determined. A ratio between the two ((area of the first inorganic particle 91)/(area of the assumed circle (91M))) can represent the ratio (R). For example, the ratio (R) is 0.95. The first exposed surface (91x) in FIG. 6E (c) is covered by the conductor layer.

The inner wall surface (27b) after the laser irradiation and the first surface (22b) after the cleaning are treated at the same time. The inner wall surface (27b) after the laser irradiation and the first surface (22b) after the cleaning are treated separately. When treated separately, both are treated using the same method. Alternatively, the two are treated using different methods.

When the inner wall surface (27b) after the laser irradiation is treated, the surface is substantially not roughened. The inner wall surface 27 has substantially no unevenness. The inner wall surface 27 is formed smooth. The surface (80a) of the resin 80 that forms the inner wall surface 27 is formed smooth. The surface (80a) of the resin 80 has substantially no unevenness. The surface (80a) of the resin 80 has an arithmetic mean roughness (Ra) of 0.2 μm or less. By controlling the conditions for treating the inner wall surface (27b) after the laser irradiation, a size of unevenness is controlled.

When the first surface (22b) after the cleaning is treated, the first surface 22 is substantially not roughened. The first surface 22 has substantially no unevenness. The first surface 22 is formed smooth. The upper surface (80R) of the resin 80 that forms the first surface 22 is formed smooth. The upper surface (80R) of the resin 80 has substantially no unevenness. The upper surface (80R) of the resin 80 has an arithmetic mean roughness (Ra) of 0.2 μm or less. By controlling the conditions for treating the first surface (22b) after the cleaning, a size of the unevenness is controlled.

The embodiment can clean the inside of the opening 26. The cleaning of the inside of the opening 26 is performed using plasma. That is, the cleaning is performed by a dry process. The cleaning includes a desmear treatment. When treating the inner wall surface (27b) after the laser irradiation includes cleaning the inside of the opening 26, the embodiment can omit the cleaning of the inside of the opening 26. When treating the first surface (22b) after the cleaning includes cleaning the inside of the opening 26, the embodiment can omit the cleaning of the inside of the opening 26. The embodiment can omit the desmear treatment.

As illustrated in FIG. 6F, the seed layer (30a) is formed on the first surface 22 of the resin insulating layer 20. The seed layer (30a) is formed by sputtering. The formation of the seed layer (30a) is performed with a dry process. The first layer (31a) is formed on the first surface 22 by sputtering. At the same time, the first layer (31a) is formed on the inner wall surface 27 and the pad 14, which are exposed from the opening 26, by sputtering. Substantially no recesses are formed on the first surface 22. Therefore, the first layer (31a) on the first surface 22 is formed substantially flat. After that, the second layer (31b) is formed on the first layer (31a) by sputtering. The second layer (31b) is formed substantially flat. The first layer (31a) and the second layer (31b) are formed in vacuum. The seed layer (30a) is also formed on the upper surface of the pad 14 exposed from the opening 26 and on the inner wall surface 27 of the opening 26. The first layer (31a) is formed of an alloy containing copper and aluminum. Aluminum has high ductility and high malleability. Therefore, adhesion between resin insulating layer 20 and the first layer (31a) is high. It is thought that, even when the resin insulating layer 20 expands and contracts due to heat cycles, the seed layer (30a) containing aluminum can follow the expansion and contraction. Even when the first surface 22 of the resin insulating layer 20 is smooth, the seed layer (30a) is unlikely to peel off from the resin insulating layer 20. It is thought that aluminum is easily oxidized. It is thought that, when the third inorganic particles 93 are inorganic particles 90 containing oxygen (oxygen elements), the first layer (31a) formed on the inner wall surface 27 adheres to the third inorganic particles 93 via the oxygen in the inorganic particles 90 forming the inner wall surface 27. The first layer (31a) and the inner wall surface 27 are strongly bonded to each other. The embodiment can increase adhesion between the inner wall surface 27 and the first layer (31a). The seed layer (30a) is unlikely to peel off from the inner wall surface 27. The third inorganic particles 93 forming the inner wall surface 27 preferably contain oxygen elements. It is thought that, when the first inorganic particles 91 are inorganic particles 90 containing oxygen (oxygen elements), the first layer (31a) formed on the first surface 22 adheres to the first inorganic particles 91 via the oxygen in the inorganic particles 90 forming the first surface 22. The first layer (31a) and the first surface 22 are strongly bonded to each other.

The embodiment can increase adhesion between the first surface 22 and the first layer (31a). The seed layer (30a) is unlikely to peel off from the first surface 22. The first inorganic particles 91 forming the first surface 22 preferably contain oxygen elements. The first layer (31a) can further contain silicon. In this case, silicon is a specific metal, and the first layer (31a) is formed of an alloy containing copper, aluminum, and silicon. When the inorganic particles 90 are glass particles, both the first layer (31a) and the first inorganic particles 91 contain silicon. It is thought that the two are strongly bonded to each other via silicon. It is thought that the embodiment can further increase adhesive strength between the first layer (31a) and the first surface 22. The first layer (31a) and the third inorganic 93 both contain silicon. It is thought that the two are strongly bonded to each other via silicon. It is thought that the embodiment can further increase the adhesive strength between the first layer (31a) and the inner wall surface 27. The second layer (31b) is formed of copper.

The first surface 22 has substantially no recesses. The inner wall surface 27 has substantially no recesses. The first surface 22 is formed substantially smooth. The inner wall surface 27 is formed substantially smooth. Therefore, even when the sputtering films (the first layer (31a) and the second layer (31b)) are thin, the embodiment can form a continuous seed layer (30a). As a result, the embodiment can form fine wirings. The embodiment can form a high-density wiring group, for example, with L/S=3/3 μm, 2/2 μm, or the like.

The first layer (31a) formed on the inner wall surface 27 may have a first portion (60a) and a second portion (70a) (FIG. 4). The first portion (60a) and the second portion (70a) are formed at the same time. The first portion (60a) and the second portion (70a) are electrically connected. A leading end (62a) of the first portion (60a) is formed on a trailing end (72a) of the second portion (70a). The first layer (31a) covering the inner wall surface 27 has a substantially step-shaped cross section. When the inner wall surface 27 has the steps (second steps), the first layer (31a) can be easily formed on the inner wall surface 27 so that the cross section of the first layer (31a) has a stepped shape. Examples of sputtering conditions are described below. A distance between a target and the first surface 22 of the resin insulating layer 20 is 50 mm or more and 250 mm or less. A voltage is 15 eV or more and 50 eV or less. A gas concentration is 0.1 Pa or more and 1.0 Pa or less.

The second layer (31b) formed on the first layer (31a) covering the inner wall surface 27 has the first portion (60b) and the second portion (70b). The first portion (60b) and the second portion (70b) are formed at the same time. The first portion (60b) and the second portion (70b) are electrically connected. A leading end (62b) of the first portion (60b) is formed on a trailing end (72b) of the second portion (70b). The second layer (31b) formed on the inner wall surface 27 has a substantially step-shaped cross section. Sputtering conditions are substantially the same as those described above.

In the printed wiring board 2 of the embodiment, a part of the first portion 60 of the seed layer (30a) covering the inner wall surface 27 of the opening 26 is formed on the second portion 70. The first portion 60 and the second portion 70 partially overlap. Therefore, the embodiment can increase the strength of the seed layer (30a). The seed layer (30a) is unlikely to break. The seed layer (30a) is formed of the substantially smooth first portion 60 and the substantially smooth second portion 70. Therefore, transmission loss is low when a high frequency signal is transmitted. A high quality printed wiring board 2 is provided.

A resin layer for forming a plating resist is formed on the seed layer (30a). The resin layer is formed by attaching a photosensitive resin film (film for the plating resist) on the seed layer (30a). It is also possible that the resin layer is formed by applying a liquid photosensitive resin on the seed layer (30a).

After the formation of the resin layer, pressure is applied to the resin layer via a gas. The application of the pressure and the formation of the resin layer are performed separately. For example, when the film for the plating resist is attached on the seed layer (30a), pressure is applied to the film for the plating resist. The pressure at this time is different from the pressure applied via a gas. When pressure is applied to the resin layer via a gas, pressure is not applied to the resin layer via a medium other than a gas. An example of a medium other than a gas is vacuum. Heat is further applied to the resin layer. The application of pressure to the resin layer and the application of heat to the resin layer are performed at the same time. The application of heat to the resin layer is performed via a gas. By applying pressure to the resin layer, the embodiment can eliminate, reduce, or minimize voids between the seed layer (30a) and the plating resist. By applying heat and pressure to the resin layer, the embodiment can eliminate, reduce, or minimize voids between the seed layer (30a) and the plating resist. For example, an intermediate substrate is arranged in a device (pressure application device) for applying pressure to the intermediate substrate. The intermediate substrate is a substrate having the seed layer (30a) and the resin layer on the seed layer (30a). After that, a gas is introduced into the pressure application device. By introducing the gas into the pressure application device, pressure is applied to the resin layer via the gas. The pressure application device can have a heater. The heater applies heat to the gas in the pressure application device. The heat is applied to the resin layer via the gas. The intermediate substrate may further have a protective film on the resin layer. When a protective film exists on the resin layer, pressure is applied to the resin layer via the protective film and the gas. Pressure and heat are applied to the resin layer through the protective film and the gas.

The resin layer is irradiated with exposure light using a DI exposure measure. DI exposure is also referred to as direct exposure. DI exposure is a type of exposure method used to form a plating resist having desired patterns. In DI exposure, light is directly irradiated to the resin layer without using a mask. Therefore, DI exposure has high productivity. Examples of DI exposure of the embodiment are described in JP 2006-301591 A and JP 2010-122526 A. The entire contents of these publications are incorporated herein by reference.

The DI exposure of the embodiment includes the following processes. As illustrated in FIG. 7, a position of a boundary between a resin layer 300 and the seed layer (30a) is measured by a sensor 400. The sensor 400 emits measurement light 500. Then, the sensor 400 measures the position by detecting the measurement light 500 reflected by an object to be detected. The sensor 400 may measure a position of an upper surface of the resin layer 300 instead of the position of the boundary between the resin layer 300 and the seed layer (30a). When a protective film is present on the resin layer 300, the sensor 400 may measure a position of a boundary between the resin layer 300 and the protective film, or a position of an upper surface of the protective film.

For example, the position of the boundary between the resin layer 300 and the seed layer (30a) is measured at a location (L1). Based on a result of the measurement, a focus of light for exposure is corrected. Based on a result of the correction, the resin layer 300 formed over a predetermined distance (between the location (L1) and a location (L2)) is irradiated with the light for exposure. A focal depth is, for example, +5 μm. Next, the position of the boundary between the resin layer 300 and the seed layer (30a) is measured at the location (L2). Based on a result of the measurement, the focus of the light is corrected. Based on a result of the correction, the resin layer 300 formed over a predetermined distance (between the location (L2) and a location (L3)) is irradiated with the light for exposure. By repeating this process, light for forming a desired pattern is irradiated to the resin layer 300.

In a conventional technology, the first surface 22 of the resin insulating layer 20 is roughened. The conventional technology forms unevenness on the first surface 22 of the resin insulating layer 20. In the conventional technology, the seed layer (30a) on the first surface 22 of the resin insulating layer 20 is expected to follow the unevenness of the first surface 22 of the resin insulating layer 20. The upper surface of the seed layer (30a) in the conventional technology is expected to have unevenness. Therefore, in the conventional technology, when the resin layer 300 is formed on the seed layer (30a), it is thought that a void 600 is formed between the seed layer (30a) and the resin layer 300 due to the unevenness on the upper surface of the seed layer (30a). In the example of FIG. 7, the void 600 is formed between the seed layer (30a) and the resin layer 300 located at the location (L2).

The location (L2) has the void 600 between the seed layer (30a) and the resin layer 300. The resin layer 300 and the void 600 are different substances. Therefore, when the measurement light 500 emitted from the sensor 400 is irradiated to the location (L2), the measurement light 500 is expected to be refracted at a boundary surface between the resin layer 300 and the void 600. Due to the influence of the void 600, the sensor 400 cannot accurately measure the position of the boundary between the seed layer (30a) and the resin layer 300. Therefore, the focus of the light for exposure is not accurately corrected. The light for exposure is irradiated to the resin layer 300 formed over a predetermined distance (between the location (L2) and the location (L3)) based on inaccurate information. For example, when the light for exposure is being irradiated, the focus of the light is not aligned. A design value and an actual value are unlikely to match. A pattern of the plating resist that is actually formed is likely to differ from a design value. Design values include widths of plating resists and distances between adjacent plating resists. The conventional technology is likely to have the void 600. The conventional technology has difficulty forming fine wirings.

On the other hand, the first surface 22 of the resin insulating layer 20 of the embodiment has substantially no recesses. The seed layer (30a) formed on the first surface 22 follows the first surface 22. The upper surface of the seed layer (30a) has substantially no recesses. When a resin layer is formed on the seed layer (30a), no voids are formed between the seed layer (30a) and the resin layer, or there are fewer voids, or the voids are small.

The location (L1) does not have a void 600 between the seed layer (30a) and the resin layer 300. Alternatively, even when there is a void 600, the void 600 is small enough not to affect the measurement of the position. Therefore, when the measurement light 500 emitted from the sensor 400 is irradiated to the location (L1), the sensor 400 can accurately measure the position of the boundary between the seed layer (30a) and the resin layer 300. Based on a result of the measurement, the focus of the light for exposure is accurately corrected. Based on accurate information, the light for exposure is irradiated to the resin layer 300 formed over a predetermined distance (between the location (L1) and the location (L2)). For example, when the exposure light is being irradiated, the focus is aligned. A pattern of a plating resist that is actually formed substantially matches a design value. The embodiment is unlikely to have a void 600 that affects measurement of a position. The embodiment can form fine wirings.

The embodiment can use high-productivity DI exposure for forming a plating resist. The plating resist has openings for forming the first signal wiring 32, the second signal wiring 34, and the land 36. When the first surface 22 has recesses, air caused by the recesses is likely to be trapped between the plating resist and the seed layer (30a). However, in the embodiment, the first surface 22 has substantially no recesses. Therefore, the seed layer (30a) on the first surface 22 is formed substantially flat. The seed layer (30a) has substantially no recesses. Air (void) is unlikely to remain between the plating resist and the seed layer (30a). A contact area between the plating resist and the seed layer (30a) is large. Even when a width of the plating resist for forming a space between the first signal wiring 32 and the second signal wiring 34 is 10 μm or less, the plating resist is unlikely to peel off from an upper surface of the seed layer (30a). Even when the width of the plating resist is 3 μm or more and 8 μm or less, the embodiment can form the plating resist on the seed layer (30a). Even when the width of the plating resist is 6 μm or less, the plating resist is unlikely to peel off from the seed layer (30a).

The electrolytic plating layer (30b) is formed on the seed layer (30a) exposed from the plating resist. The electrolytic plating layer (30b) is formed of copper. The electrolytic plating layer (30b) fills the opening 26. The first signal wiring 32, the second signal wiring 34, and the land 36 are formed by the seed layer (30a) and the electrolytic plating film (30b) on the first surface 22. The second conductor layer 30 is formed. The via conductor (first via conductor) 40 is formed by the seed layer (30a) and the electrolytic plating film (30b) in the opening 26. The via conductor 40 connects the pad 14 and the land 36. The first signal wiring 32 and the second signal wiring 34 form a pair wiring. The first via conductor 40 connects the conductor layer (first conductor layer) 10 and the conductor layer (second conductor layer) 30.

The plating resist is removed. The seed layer (30a) exposed from the electrolytic plating layer (30b) is removed. The seed layer (30a) is removed by wet etching. An etching solution used in the wet etching is an aqueous solution containing hydrogen peroxide and sulfuric acid. By the wet etching, the first layer (31a) and the second layer (31b) are removed at the same time. The second conductor layer 30 and the via conductor 40 are formed at the same time. A width (D2) of the first layer (31a) is larger than a width (D3) of the second layer (31b), and a width (D1) of the electrolytic plating layer (30b) is larger than the width (D2) of the first layer (31a). An etching rate of the seed layer (30a) is higher than an etching rate of the electrolytic plating layer (30b). The etching rate of the seed layer is 1.1 to 1.5 times the etching rate of the electrolytic plating layer. The seed layer (30a) formed by sputtering has a higher ratio of an amorphous structure part to a metal crystal part compared to the electrolytic plating layer (30b). The amorphous structure part has more crystal defects. The greater the amount of crystal defects, the higher the etching rate. The etching rate of the seed layer (30a) is higher than the etching rate of the electrolytic plating layer (30b). Therefore, when the seed layer (30a) is removed, an etching amount of the electrolytic plating layer (30b) is small. A conductive circuit is unlikely to be excessively etched. In the embodiment, a width of a conductor circuit substantially matches a design value. When the seed layer (30a) is removed by etching, the width of the seed layer (30a) forming the conductive circuits (the first signal wiring 32, the second signal wiring 34, and the land 36) of the second conductor layer 30 is smaller than the width of the electrolytic plating layer (30b). When the first layer (31a) is formed of a copper alloy and the second layer (31b) is formed of copper, only the first layer (31a) is formed of an alloy. Therefore, the embodiment can increase a difference in etching rate between the two. As an etching solution for removing the seed layer (30a), an etching solution that dissolves the second layer (31b) more than the first layer (31a) is preferable. A width of a wiring (a distance between sidewalls of the wiring) is smallest at the boundary portion (B) between the second layer (31b) and the electrolytic plating layer (30b). Since a stress is the largest at the boundary portion (B), the adhesion between the first layer (31a) and the first resin insulating layer 20 is improved.

Since the first surface 22 is substantially flat, the embodiment can reduce the thickness of the first layer (31a). The thickness of the first layer (31a) is sufficiently smaller than the thickness of the electrolytic plating layer (30b). Therefore, orientation of the particles forming the first layer (31a) tends to be lower than orientation of the particles forming the electrolytic plating layer (30b). Alternatively, a density of the first layer (31a) tends to be smaller than a density of the electrolytic plating layer (30b). Alternatively, crystallinity of the first layer (31a) tends to be lower than crystallinity of the electrolytic plating layer (30b). Since the first surface 22 is substantially flat, the embodiment can reduce the thickness of the second layer (31b). The thickness of the second layer (31b) is sufficiently smaller than the thickness of the electrolytic plating layer (30b). Therefore, orientation of the particles forming the second layer (31b) tends to be lower than the orientation of the particles forming the electrolytic plating layer (30b). Alternatively, a density of the second layer (31b) tends to be smaller than the density of the electrolytic plating layer (30b). Alternatively, crystallinity of the second layer (31b) tends to be lower than the crystallinity of the electrolytic plating layer (30b). Therefore, the etching rates of the first layer (31a) and the second layer (31b) are higher than the etching rate of the electrolytic plating layer (30b). When the seed layer (30a) exposed from the electrolytic plating layer (30b) is removed, the width (D1) of the electrolytic plating layer (30b) is larger than the width (D2) of the first layer (31a). The width (D1) of the electrolytic plating layer (30b) is larger than the width (D3) of the second layer (31b). The etching rate of the electrolytic plating layer (30b) is smaller than the etching rate of the seed layer (30a). Therefore, an amount of a dissolution component in an etching solution consumed for dissolving the electrolytic plating layer (30b) is small. According to the embodiment, a dissolution component sufficiently reaches the seed layer (30a). The seed layer (30a) efficiently dissolves. The embodiment can form a signal wiring having a target width. The first layer (31a) is covered by the second layer (31b). A dissolution component is consumed for dissolving the second layer (31b). Therefore, in the embodiment, a dissolution amount of the first layer (31a) can be smaller than a dissolution amount of the second layer (31b). When the seed layer (30a) exposed from the electrolytic plating layer (30b) is removed, the width (D2) of the first layer (31a) is larger than the width (D3) of the second layer (31b).

The resin insulating layer (second resin insulating layer) 120 is formed on the first surface 22 of the first resin insulating layer 20 and on the second conductor layer 30 using a method similar to that for the first resin insulating layer 20. The second resin insulating layer 120 has the first surface 122, the second surface 124 on the opposite side with respect to the first surface 122, and the opening (via conductor opening) 126. The second surface 124 of the second resin insulating layer 120 faces the second conductor layer 30. The second conductor layer 30 is exposed by the opening 126. The conductor layer (third conductor layer) 130 is formed on the first surface 122 of the second resin insulating layer 120 using a method similar to that for the second conductor layer 30. The via conductor (second via conductor) 140 that connects the second conductor layer 30 and the third conductor layer 130 is formed in the opening (second opening) 126 using a method similar to that for the first via conductor 40. The printed wiring board 2 of the embodiment is obtained.

The resin insulating layers are each formed of a resin 80 and inorganic particles 90. The resin forming each of the resin insulating layers and the resin 80 forming the first resin insulating layer 20 are similar. The inorganic particles forming each of the resin insulating layers and the inorganic particles 90 forming the first resin insulating layer 20 are similar. The resin insulating layers each include first inorganic particles, second inorganic particles, and third inorganic particles. The particles in each of the resin insulating layers and the particles in the first resin insulating layer 20 are similar. The resin insulating layers each have a first surface. The first surface of each of the resin insulating layers and the first surface 22 of the first resin insulating layer 20 are similar. The resin insulating layers each have an opening (via conductor opening). The opening penetrating each of the resin insulating layers and the opening 26 penetrating the first resin insulating layer are similar. An inner wall surface of the opening penetrating each of the resin insulating layers and the inner wall surface 27 of the opening 26 penetrating the first resin insulating layer 20 are similar.

The conductor layers are each formed of a seed layer and an electrolytic plating layer on the seed layer. The seed layer forming each of the conductor layers and the seed layer (30a) forming the second conductor layer 30 are similar. The first layer forming each of the conductor layers and the first layer (31a) forming the second conductor layer 30 are similar. The second layer forming each of the conductor layers and the second layer (31b) forming the second conductor layer 30 are similar. The electrolytic plating layer forming each of the conductor layers and the electrolytic plating layer (30b) forming the second conductor layer 30 are similar.

The via conductors are each formed of a seed layer and an electrolytic plating layer on the seed layer. The seed layer forming each of the via conductors and the seed layer (30a) forming the first via conductor 40 are similar. The first layer forming each of the via conductors and the first layer (31a) forming the first via conductor 40 are similar. The second layer forming each of the via conductors and the second layer (31b) forming the first via conductor 40 are similar. The electrolytic plating layer forming each of the via conductors and the electrolytic plating layer (30b) forming the first via conductor 40 are similar.

In the printed wiring board 2 of the embodiment, substantially no recesses are formed on the first surface 22 of the resin insulating layer 20. The first surface 22 of the resin insulating layer 20 is substantially flat. The upper surface of the seed layer (30a), which is formed on the first surface 22 of the resin insulating layer 20 by sputtering, is also substantially flat. When an electrical signal propagates through the signal wiring, the embodiment can reduce transmission loss. Since the seed layer (30a) is formed by sputtering, adhesion strength between the resin insulating layer 20 and the seed layer (30a) is high. A conductor circuit is unlikely to peel off from the resin insulating layer 20. Even when the sputtering film is thin, the embodiment can form a continuous seed layer (30a). When the seed layer (30a) is removed, the embodiment can reduce an etching amount. Further, since the upper surface of the seed layer (30a) is substantially flat, the embodiment can form a fine plating resist having dimensions close to target values using DI exposure. The embodiment can form fine signal wirings. The embodiment can form a high-quality printed wiring board 2.

Even when the sputtering film is thin, the embodiment can form a continuous seed layer (30a). The inner wall surface 27 of the opening 26 is formed by the flat parts (93a) of the third inorganic particles 93 and the resin 80. The flat parts (91a) and the surface (80a) of the resin 80 that forms the inner wall surface 27 form a common surface. The inner wall surface 27 is formed smooth. Therefore, a seed layer (30a) having a uniform thickness is formed on the inner wall surface 27 of the opening 26. The seed layer (30a) is thin. The first surface 22 is formed by the exposed portions (91P) of the first inorganic particles 91 and the upper surface (80R) of the resin 80. The exposed surfaces (91x) and the upper surface (80R) of the resin 80 form a common surface. The first surface 22 is formed smooth. Therefore, the seed layer (30a) having a uniform thickness is formed on the first surface 22. The seed layer (30a) is thin. When the seed layer (30a) is removed, an etching amount is small. Therefore, an etching amount of the electrolytic plating layer (30b) is small. The second conductor layer 30 having the first signal wiring 32 and the second signal wiring 34 has a width as designed. Fine wirings are formed. A high quality printed wiring board 2 is provided.

When the first layer (31a) of the seed layer (30a) contains aluminum and the third inorganic particles 93 contain oxygen elements, the embodiment can increase the adhesive strength between the first layer (31a) and the inner wall surface 27. Even when the opening 26 has a small diameter, the via conductor 40 is unlikely to peel off from the inner wall surface 27. Therefore, connection resistance via the via conductor 40 is unlikely to increase. As illustrated in FIG. 6F, a diameter (D) of the via conductor 40 (the diameter of the opening 26) is measured on the pad 14. The diameter (D) is 20 μm or more and 50 μm or less. Even when a length of each side of the printed wiring board 2 exceeds 50 mm, the connection resistance via the via conductor 40 is unlikely to increase. Even when the length of each side of the printed wiring board 2 is 100 mm or more, the connection resistance is unlikely to increase for a long period. A printed wiring board 2 with high connection reliability is provided.

The embodiment can reduce the thickness of the first layer (31a) forming the via conductor 40. The embodiment can reduce the thickness of the second layer (31b) forming the via conductor 40. The first layer (31a) and the second layer (31b) form the seed layer (30a). The embodiment can increase a volume of the via conductor opening after the formation of the seed layer. The via conductor opening after the formation of the seed layer may be referred to as a post-seed layer formation opening. By forming an electrolytic plating layer in the post-seed layer formation opening, a via conductor including the seed layer and the electrolytic plating layer is formed. Even when the via conductor opening has a small diameter, an electrolytic plating solution can easily enter the post-seed layer formation via conductor opening. The electrolytic plating layer forming the via conductor is unlikely to contain a void. A low resistance via conductor is formed. An example of a post-seed layer formation opening 260 is illustrated in FIG. 6F. The post-seed layer formation opening 260 is surrounded by the seed layer. The bottom and side surface of the opening 260 are in contact with the seed layer.

The embodiment can reduce the thickness of the first layer (31a) formed of an alloy containing aluminum. In the signal wirings, a content of aluminum is low and a content of copper is high. The embodiment can provide low-resistance signal wirings. The embodiment can provide low-resistance signal wirings with high adhesion to the resin insulating layers.

In the printed wiring board 2 of the embodiment, the first surface 22 of the resin insulating layer 20 has substantially no recesses. An increase in standard deviation of a relative permittivity in a portion near the first surface 22 of the resin insulating layer 20 is suppressed. The relative permittivity of the first surface 22 of the resin insulating layer 20 does not significantly vary depending on a location. Even when the multiple signal wirings are in contact with the first surface 22 of the resin insulating layer 20, the embodiment can reduce a difference in electrical signal propagation speed between the signal wirings. Therefore, in the printed wiring board 2 of the embodiment, noise is suppressed. Even when a logic IC is mounted on the printed wiring board 2 of the embodiment, data transmitted via the signal wirings reaches the logic IC substantially simultaneously. The embodiment can suppress malfunction of the logic IC. Even when the signal wirings each have a length of 5 mm or more, the embodiment can reduce the difference in propagation speed. Even when the signal wirings each have a length of 10 mm or more and 20 mm or less, the embodiment can suppress malfunction of the logic IC. The first surface 122 of the second resin insulating layer 120 is also similar to the first surface 22 of the resin insulating layer 20. Therefore, signal wirings in the third conductor layer 130 also have similar effects as the signal wirings in the second conductor layer 30. A high quality printed wiring board 2 is provided.

When the first layer contains silicon as the specific metal and the inorganic particles are glass particles, the first layer and the third inorganic particles 93 on the inner wall surface contain silicon. The first layer on the first surface and the first inorganic particles 91 contain silicon. It is thought that the two are strongly bonded to each other via silicon. The seed layer formed of an alloy containing copper, aluminum, and silicon is unlikely to peel off from the inner wall surface. The seed layer is unlikely to peel off from the first surface. The seed layer is unlikely to peel off from the resin insulating layer.

When the first layer contains aluminum and the inorganic particles 90 (the first inorganic particles 91, the second inorganic particles 92, and the third inorganic particles 93) contain oxygen, it is thought that the first layer and the inorganic particles 90 (oxygen-containing inorganic particles such as glass particles) are strongly bonded to each other. When the first layer contains aluminum and the inorganic particles 90 contain oxygen, the first layer may be formed of copper, aluminum, and impurities.

### First Alternative Example

In a first alternative example of the embodiment, the specific metal is selected from titanium, nickel, chromium, tin and calcium.

### Second Alternative Example

In a second alternative example of the embodiment, the first layers (11a, 31a) of the seed layers (10a, 30a) are each formed of copper and a second element. The second element is selected from silicon, aluminum, titanium, nickel, chromium, carbon, oxygen, tin, and calcium. The first layers (11a, 31a) are formed of an alloy containing copper. The second layers (11b, 31b) are formed of copper. A content of copper forming the second layers (11b, 31b) is 99.9 at % or more, The content of copper is preferably 99.95 at % or more.

The cross-sectional views are each obtained by cutting the printed wiring board 2 with a surface perpendicular to the first surface 22. When a cross-sectional view includes a conductor circuit, a side surface of the conductor circuit is perpendicular to the cross-sectional view.

In the present specification, the term “flat surface” is used in reference to the shape of the first surface 22, the shapes of the exposed surfaces (91x), the shapes of the first inorganic particles 91, the shape of the inner wall surface 27, the shapes of the flat parts (93a), and the shapes of the third inorganic particles 93. The meaning of the “flat surface” used in relation to these elements is illustrated in FIGS. 1-3. That is, in FIGS. 1 and 2, the first surface 22 is drawn substantially straight. The shape of the first surface 22 in FIGS. 1 and 2 is substantially a straight line. In FIGS. 1 and 3, the inner wall surface 27 is depicted substantially straight. The shape of the inner wall surface 27 in FIGS. 1 and 3 is substantially a straight line. The term “flat surface” in the present specification includes a substantially straight line illustrated in a cross section. As illustrated in the cross sections of the first inorganic particles 91 and the cross sections of the third inorganic particles 93 in FIGS. 1 to 3, in a cross section, cutting along a flat surface includes cutting along a straight line. The term “flat surface” in the present specification does not mean a perfect flat surface, but includes a substantially flat surface. A substantially flat surface may include small unevenness.

Japanese Patent Application Laid-Open Publication No. 2001-217526 describes a method for manufacturing a printed wiring board. Japanese Patent Application Laid-Open Publication No. 2001-217526 describes a manufacturing method that includes forming a non-through hole in an insulating resin layer, forming fine unevenness on a surface of the insulating resin layer, forming a power feeding layer by electroless copper plating, and forming a plating resist using a photomask. The plating resist is removed using an oxidizing agent.

According to Japanese Patent Application Laid-Open Publication No. 2001-217526, the power feeding layer (seed layer) is an electroless copper plating film formed on the surface of the insulating resin layer having unevenness. It is thought that the power feeding layer follows the unevenness of the surface of the insulating resin layer. It is thought that an upper surface of the power feeding layer has unevenness. It is thought that the embodiment of Patent Document 1 cannot reduce transmission loss of wirings due to the unevenness of the power feeding layer. It is thought that a contact area between a photoresist for forming the plating resist and the power feeding layer is small due to the unevenness of the upper surface of the power feeding layer. It is thought that the plating resist peels off from the power feeding layer due to development. It is thought that peeling is particularly likely to occur when the plating resist has a small width. It is thought that the embodiment of Patent Document 1 has difficulty forming fine wirings.

A method for manufacturing a printed wiring board according to an embodiment of the present invention includes forming a resin insulating layer on a first conductor layer, the resin insulating layer having a first surface and a second surface on the opposite side with respect to the first surface; forming a protective film on the first surface of the resin insulating layer; forming a via conductor opening that penetrates the protective film and the resin insulating layer at the same time and reaches the first conductor layer; removing the protective film from the resin insulating layer after the forming of the opening; treating the first surface of the resin insulating layer; forming a second conductor layer on the first surface of the resin insulating layer; and forming a via conductor in the opening connecting the first conductor layer and the second conductor layer. The resin insulating layer contains a resin and inorganic particles. The inorganic particles include first inorganic particles forming the first surface and second inorganic particles embedded in the resin. The first inorganic particles have substantially truncated spherical shapes. The second inorganic particles have substantially spherical shapes. The first inorganic particles each have a substantially flat exposed portion. The resin has an upper surface forming the first surface. The first surface is formed by the upper surface of the resin and the exposed portions of the first inorganic particles. The treating of the first surface includes forming the first inorganic particles from the second inorganic particles. The forming of the second conductor layer includes: forming a seed layer on the first surface of the resin insulating layer by sputtering; forming a plating resist on the seed layer using DI exposure; forming an electrolytic plating layer on the seed layer exposed from the plating resist; removing the plating resist; and removing the seed layer exposed from the electrolytic plating layer.

According to a method for manufacturing a printed wiring board of an embodiment of the present invention, substantially no recesses are formed on the first surface of the resin insulating layer. The first surface of the resin insulating layer is substantially flat. The upper surface of the seed layer, which is formed on the first surface of the resin insulating layer by sputtering, is also substantially flat. For example, when an electrical signal propagates through a signal wiring, the embodiment can reduce transmission loss. Since the seed layer is formed by sputtering, adhesion strength between the resin insulating layer and the seed layer is high. A conductor circuit is unlikely to peel off from the resin insulating layer. Even when the sputtering film is thin, the embodiment can form a continuous seed layer. When the seed layer is removed, the embodiment can reduce an etching amount required for removing the seed layer. Further, since the upper surface of the seed layer is substantially flat, the embodiment can form a fine plating resist having dimensions close to target values by using DI exposure. The embodiment can form fine signal wirings. The embodiment can form a high-quality printed wiring board.

Obviously, numerous modifications and variations of the present invention are possible in light of the above teachings. It is therefore to be understood that within the scope of the appended claims, the invention may be practiced otherwise than as specifically described herein.

1. A method for manufacturing a printed wiring board, comprising:
forming a resin insulating layer on a first conductor layer;
forming a protective film on a surface of the resin insulating layer;
forming a via conductor opening penetrates through the protective film and the resin insulating layer such that the via conductor opening reaches the first conductor layer;
removing the protective film from the resin insulating layer after the forming of the via conductor opening;
treating the surface of the resin insulating layer after the removing of the protective film;
forming a second conductor layer on the surface of the resin insulating layer after the treating of the surface of the resin insulating layer; and
forming a via conductor in the via conductor opening such that the via conductor connects the first conductor layer and the second conductor layer,
wherein the resin insulating layer includes resin and inorganic particles including first particles and second particles such that the first particles have substantially truncated spherical shapes and are forming the surface of the resin insulating layer and the second particles have substantially spherical shapes and are embedded in the resin, the treating the surface of the resin insulating layer includes forming the first particles from the second particles such that the surface of the resin insulating layer includes a surface of the resin and substantially flat exposed portions of the first particles, and the forming the second conductor layer includes forming a seed layer on the surface of the resin insulating layer by sputtering, forming a plating resist on the seed layer using DI exposure, forming an electrolytic plating layer on the seed layer exposed from the plating resist, removing the plating resist, and removing the seed layer exposed from the electrolytic plating layer.

2. The method for manufacturing a printed wiring board according to claim 1, wherein the treating the surface of the resin insulating layer includes selectively removing the resin such that the second particles protrude from the surface of the resin insulating layer.

3. The method for manufacturing a printed wiring board according to claim 1, wherein the resin insulating layer is formed such that a ratio of a volume of the first particles to a volume of spheres envisioned from the first particles is 0.6 or more.

4. The method for manufacturing a printed wiring board according to claim 1, wherein the surface of the resin insulating layer is not roughened before the forming of the seed layer.

5. The method for manufacturing a printed wiring board according to claim 1, wherein the second conductor layer has a conductor circuit, the seed layer has a first layer formed on the first surface and a second layer formed on the first layer, and the conductor circuit includes the seed layer and the electrolytic plating layer on the seed layer such that a width of the first layer is larger than a width of the second layer and that a width of the electrolytic plating layer is larger than the width of the first layer.

6. The method for manufacturing a printed wiring board according to claim 1, wherein the seed layer of the second conductor layer has a first layer formed on the surface and a second layer formed on the first layer such that the first layer is formed of an alloy comprising copper and aluminum and that the second layer is formed of copper.

7. The method for manufacturing a printed wiring board according to claim 1, wherein the inorganic particles in the resin insulating layer include third particles forming an inner wall surface in the via conductor opening such that the third particles are formed by treating the inner wall surface and that each of the third particles has a flat part forming the inner wall surface in the via conductor opening and has a substantially truncated spherical shape.

8. The method for manufacturing a printed wiring board according to claim 7, wherein the forming the via conductor opening includes forming the inorganic particles having protruding portions protruding from the resin forming the inner wall surface in the via conductor opening, and the third inorganic particles are formed by removing the protruding portions of the inorganic particles.

9. The method for manufacturing a printed wiring board according to claim 1, wherein the seed layer formed on an inner wall surface in the via conductor opening has a substantially step-shaped cross section.

10. The method for manufacturing a printed wiring board according to claim 1, wherein the forming the plating resist includes forming a resin layer on the seed layer and applying pressure to the resin layer via a gas.

11. The method for manufacturing a printed wiring board according to claim 10, wherein the applying the pressure is conducted after the forming of the resin layer.

12. The method for manufacturing a printed wiring board according to claim 11, wherein the forming the plating resist includes applying heat to the resin layer such that the applying the pressure and the applying the heat are conducted in a same process.

13. The method for manufacturing a printed wiring board according to claim 12, wherein the applying the pressure and the forming the resin layer are conducted in separate processes.

14. The method for manufacturing a printed wiring board according to claim 13, wherein the applying the heat is conducted via the gas.

15. The method for manufacturing a printed wiring board according to claim 2, wherein the resin insulating layer is formed such that a ratio of a volume of the first particles to a volume of spheres envisioned from the first particles is 0.6 or more.

16. The method for manufacturing a printed wiring board according to claim 2, wherein the surface of the resin insulating layer is not roughened before the forming of the seed layer.

17. The method for manufacturing a printed wiring board according to claim 2, wherein the second conductor layer has a conductor circuit, the seed layer has a first layer formed on the first surface and a second layer formed on the first layer, and the conductor circuit includes the seed layer and the electrolytic plating layer on the seed layer such that a width of the first layer is larger than a width of the second layer and that a width of the electrolytic plating layer is larger than the width of the first layer.

18. The method for manufacturing a printed wiring board according to claim 2, wherein the seed layer of the second conductor layer has a first layer formed on the surface and a second layer formed on the first layer such that the first layer is formed of an alloy comprising copper and aluminum and that the second layer is formed of copper.

19. The method for manufacturing a printed wiring board according to claim 2, wherein the inorganic particles in the resin insulating layer include third particles forming an inner wall surface in the via conductor opening such that the third particles are formed by treating the inner wall surface and that each of the third particles has a flat part forming the inner wall surface in the via conductor opening and has a substantially truncated spherical shape.

20. The method for manufacturing a printed wiring board according to claim 19, wherein the forming the via conductor opening includes forming the inorganic particles having protruding portions protruding from the resin forming the inner wall surface in the via conductor opening, and the third inorganic particles are formed by removing the protruding portions of the inorganic particles.
